(19) United States
(12) Patent Application Publication
(10) Pub. No.: US 2009/0169726 A1
(43) Pub. Date: Jul. 2, 2009

(54) BODY HAVING A JUNCTION AND METHOD OF MANUFACTURING THE SAME

(75) Inventors: Tomoyuki FUJII, Nagoya-shi (JP); Junya Waki, Handa-shi (JP)

Correspondence Address: BURR & BROWN, PO BOX 7068, SYRACUSE, NY, 13261-7068, US

(73) Assignee: NGK Insulators, Ltd., Nagoya-City (JP)

(21) Appl. No.: 12/199,943

(22) Filed: Aug. 28, 2008

Related U.S. Application Data
(60) Provisional application No. 60/968,945, filed on Aug. 30, 2007.

(30) Foreign Application Priority Data
Aug. 25, 2008 (JP) 2008-215807

(51) Int. Cl. B05D 5/12; H01L 21/306; C23C 16/54

(52) U.S. Cl. 427/77; 204/298.12; 204/298.31; 156/345.52; 118/725

(57) ABSTRACT

A body having a junction contains a ceramics member including alumina in which an inner electrode is embedded, having a bore region extending from a surface to the inner electrode, a surface of a bottom surface of the bore region being made rough, and a terminal hole extending to the inner electrode being provided in a part of the bottom surface; a conductive terminal embedded in the terminal hole, a bottom surface is in contact with the inner electrode, and a top surface is exposed at a horizontal level of the bottom surface of the bore region; a solder junction layer contacting with the bottom surface of the bore region including the top surface; and a conductive connection member so that a lower end surface is in contact with the solder junction layer, a lower portion is inserted into the bore region.

### CROSS-REFERENCE TO RELATED APPLICATION AND INCORPORATION BY REFERENCE

This application claims benefit of priority under 35 USC 119 based on U.S. Patent Application 60/968,945, filed Aug. 30, 2007, and Japanese Patent Application JP2008-215807 filed, Aug. 25, 2008 the entire contents of which are incorporated by reference herein.

### BACKGROUND OF THE INVENTION

1. Field of the Invention

The present invention relates to a body having a junction and a method of manufacturing the same. More particularly, the present invention relates to a body having a junction in which a connection member is joined to a terminal embedded in a ceramics member, and a body having a junction having a connection member for supplying electric power to an embedded electrode, and a method of manufacturing the same.

2. Description of the Related Art

In the field of semiconductor manufacturing apparatuses, such as an etching apparatus, a CVD apparatus and the like, a semiconductor susceptor is used for an electrostatic check and the like, in which an electrode is embedded in a ceramics member. For example, the semiconductor susceptor in which an electrode is embedded in a substrate made of aluminum nitride or fine alumina and functions as a discharge electrode for generating a plasma. Another example is a semiconductor susceptor in which a metallic resistance unit (heater) is embedded in an aluminum nitride or alumina substrate. The resistance unit functions as a ceramic heater for controlling the temperature of a wafer in a thermal treatment process such as CVD and the like. Also, in steps such as the feeding of a semiconductor wafer, a film forming process, such as exposure, CVD, sputtering, fine machining, cleaning, etching, dicing and the like, an electrode may be embedded even in the semiconductor susceptor that functions as an electrostatic chuck for holding the semiconductor wafer (for example, Japanese Laid Open Patent Application (JP-P 2006-196864A)).

A current is supplied from outside through the body having a junction to the electrode embedded in a semiconductor supporting apparatus such as the electrostatic check. For example, the body having a junction contains: a ceramics member in which an inner electrode is embedded, a bore portion extending from a surface to the inner electrode, and a terminal hole extending from the bottom surface of the bore to the inner electrode; a terminal embedded in the terminal hole so that a bottom surface is in contact with the inner electrode and further the top surface is exposed to the bottom surface of the bore region; a solder junction layer in contact with the bottom surface of the bore region including the top surface; and a connection member inserted into the bore region so as to contact the solder junction layer. The joint strength between the ceramics member and the connection member is provided by the junction portion between the side of the bore region in the ceramics member and the connection member.

However, in response to requests to improve the thermal response characteristics for the semiconductor supporting apparatus, there is a tendency to provide a thinner ceramics member, i.e., thinned from 10 mm to 2 mm, and although the depth of 3 mm or more is conventionally reserved, the depth of the bore is slightly reduced to about 0.5 mm. Consequently, the contact area between the side of the bore in the ceramics member and the connection member is decreased. The reduced contact area raises a concern that the joint strength between the ceramics member and the connection member is decreased.

For this reason, a body having a junction that can maintain the connection strength, even if the bore depth of the ceramics member into which the connection member is inserted, is shallow is required, as is a method of manufacturing the same.

### SUMMARY OF THE INVENTION

According to a first aspect of the present invention, a body having a junction, including: a ceramics member in which a plate-shaped inner electrode is embedded, having a bore region extending from a surface of the ceramics member to the inner electrode, a surface of a bottom surface of the bore region being made rough, and a terminal hole extending to the inner electrode being provided in a part of the bottom surface, and a main component of the ceramics member being alumina; a conductive terminal embedded in the terminal hole, a bottom surface thereof is in contact with the inner electrode, and a top surface thereof is exposed at a horizontal level of the bottom surface of the bore region; a solder junction layer in contact with the bottom surface of the bore region including the top surface; and a conductive connection member having a lower end surface in contact with the solder junction layer with a lower portion inserted into the bore region, and having a thermal expansion coefficient in a range between about 6.5 and about 9.5 ppm/K.

According to a second aspect of the present invention, the method of manufacturing the body having a junction includes: forming a plate-shaped inner electrode on a top surface of a first ceramics layer having a main component of alumina; placing a terminal made of sinter on the inner electrode so that a bottom surface thereof is in contact with a part of a top surface of the inner electrode; covering the terminal and the inner electrode by placing a baking material having a main component of alumina and baking the baking material and consequently providing a second ceramics layer so as to obtain a ceramics member in which the inner electrode and the terminal are embedded between the first ceramics layer and the second ceramics layer; forming a bore region extending from a surface of the ceramics member to the inner electrode and exposing a top surface of the terminal to a part of a bottom surface of the bore region; roughing the bottom surface of the bore so that a surface roughness of the bottom surface of the bore is in a range of Ra=about 0.7 to about 2.0 μm; forming a plating layer including Ni between the bottom surface and a joining material layer; forming a solder junction layer on the bottom surface of the bore region including the top surface of the terminal; and roughing a contact surface with the solder junction layer so that a surface roughness Ra is in a range of about 1 to about 3 μm, and inserting a lower portion of the connection member into the bore region so that a lower end surface of a conductive connection member having a thermal expansion coefficient in a range of about 6.5 and about 9.5 ppm/K is in contact with the solder junction layer.

### BRIEF DESCRIPTION OF THE DRAWINGS

FIG. 1A shows a sectional schematic view that is obtained when a semiconductor susceptor according to a first embodiment is cut in a longitudinal direction, FIG. 1B shows a sectional schematic view when it is viewed from A1-A2 obtained by cutting in parallel to the surface of the ceramics member in the semiconductor susceptor according to the first embodiment, and FIG. 1C shows a sectional schematic view when it is viewed from B1-B2 obtained by cutting in parallel to the surface of the ceramics member in the semiconductor susceptor according to the first embodiment.

FIG. 2 shows a manufacturing step view (No. 1) of the semiconductor susceptor according to the first embodiment.

FIG. 3 shows a manufacturing step view (No. 2) of the semiconductor susceptor according to the first embodiment.

FIG. 4 shows a manufacturing step view (No. 3) of the semiconductor susceptor according to the first embodiment.

FIG. 5 shows a manufacturing step view (No. 4) of the semiconductor susceptor according to the first embodiment.

FIG. 6 shows a manufacturing step view (No. 5) of the semiconductor susceptor according to the first embodiment.

FIG. 7 shows a manufacturing step view (No. 6) of the semiconductor susceptor according to the first embodiment.

FIG. 8 shows a manufacturing step view (No. 7) of the semiconductor susceptor according to the first embodiment.

FIG. 9A shows a sectional schematic view that is obtained when a semiconductor susceptor according to a second embodiment is cut in a longitudinal direction, and FIG. 9B shows a sectional schematic view that is obtained by cutting in parallel to the surface of the ceramics member in the semiconductor susceptor according to the second embodiment.

FIG. 10A and FIG. 10B show a manufacturing step view (No. 1) of the semiconductor susceptor according to the second embodiment.

FIG. 11A and FIG. 11B show a manufacturing; step view (No. 2) of the semiconductor susceptor according to the second embodiment.

FIG. 12 shows a manufacturing step view (No. 3) of the semiconductor susceptor according to the second embodiment.

FIG. 13A shows a sectional schematic view that is obtained when a semiconductor susceptor according to a variation 1 of the second embodiment is cut in a longitudinal direction, and FIG. 13B shows a sectional schematic view that is obtained by cutting in parallel to the surface of the ceramics member in the semiconductor susceptor according to the variation 1 of the second embodiment.

FIG. 14 shows a sectional schematic view of a joining strength measurement of the body having a junction in the semiconductor susceptor.

FIG. 15 shows a schematic view of an electrostatic chuck used in a thermal uniformity test.

FIGS. 16 A (example), 16B (preferable example) show contour lines traced from a temperature distribution when a surface of a substrate placement side around a terminal 3 is measured from a thermo photography.

### DETAILED DESCRIPTION OF THE INVENTION

The present invention provides a body having a junction that can maintain its connection strength, even if the depth of a bore region in a ceramics member, into which a connection member is inserted, is shallow, and a method of manufacturing the same.

The present invention will be described below by referring to the embodiments. However, the present invention is not limited to the following embodiments. In the drawings, the same or similar symbol is assigned to elements having same function or similar function, and repetitive descriptions are omitted. Also, in this specification, the definitions of [Top] and [Bottom], such as a top surface, a bottom surface and the like are merely used for convenience. Depending on the selection manner in an actual direction, [Top] and [Bottom] may be reversed, or they may be oblique.

### First Embodiment

### Semiconductor Susceptor (Body having a Junction)

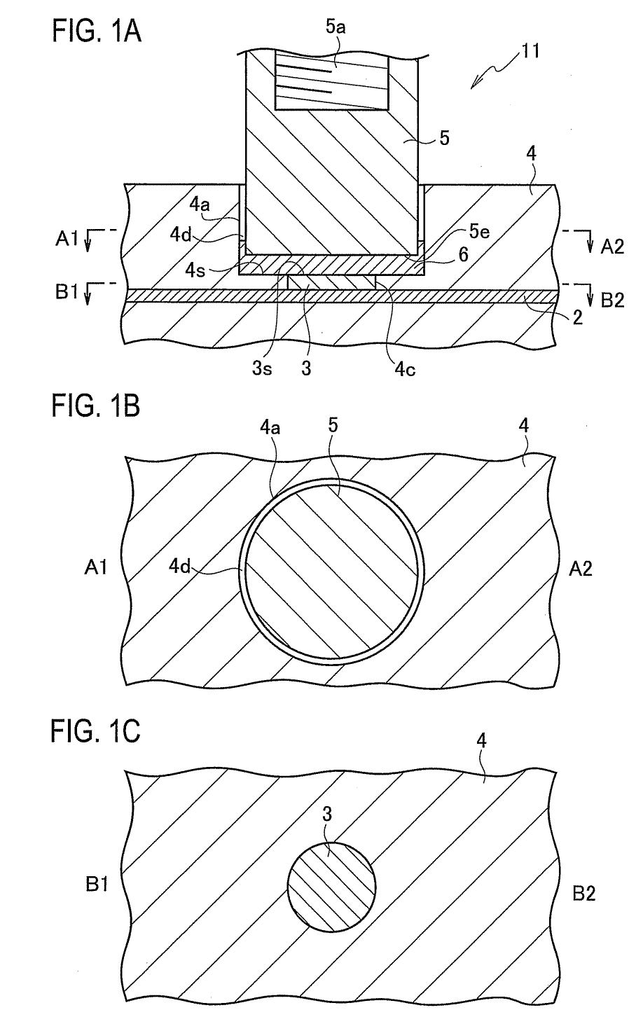

FIG. 1A shows a sectional schematic view obtained by cutting in a longitudinal direction of a semiconductor susceptor 11 according to a first embodiment. FIG. 1B shows a sectional schematic view when viewed from A1-A2 obtained by cutting in parallel to the surface of the ceramics member in the semiconductor susceptor 11 according to the embodiment.

FIG. 1C shows a sectional schematic view when viewed from B1-B2 obtained by cutting in parallel to the surface of a ceramics member 4 in the semiconductor susceptor 11 according to the first embodiment. The semiconductor susceptor 11 according to the first embodiment is described and the body having a junction and the semiconductor manufacturing apparatus having the body having a junction are also described.

The semiconductor susceptor 11 according to the first embodiment includes a ceramics member 4 in which a plate-shaped inner electrode 2 is embedded. A bore region 4a extends from a surface of the ceramics member 4 to the inner electrode 2. A surface of a bottom surface of the bore region is made rough. A terminal hole 4c extends toward the inner electrode 2 is provided in a part of the bottom surface 4s of the bore region 4a. The main component of the ceramics member 4 is alumina. A conductive terminal 3 is embedded in the terminal hole 4c so that a bottom surface of the conductive terminal 3 is in contact with the inner electrode. A top surface 3s is exposed to a horizontal level of the bottom surface 4s of the bore region 4a. A solder junction layer 6 is in contact with the bottom surface 4s of the bore region 4a including the top surface 3s. A conductive connection member 5 has a bottom portion is inserted into the bore region 4a so that a low end surface 5e is in contact with the solder junction layer, and a thermal expansion coefficient of the conductive connection member 5 is in a range between about 6.5 and about 9.5 ppm/K.

According to the first embodiment, a body having a junction is provided that can maintain connection strength, even if the depth of the bore region in the ceramics member into which the connection member is inserted is shallow is provided. A method of manufacturing the junction structure is also provided.

A preferred material for the ceramics member 4 includes alumina (Al₂O₃) as a main component. In order to have a higher electric resistivity, the purity of the alumina is preferred to be 99% or more, and more preferably to be 99.5% or more. In this case, an electrostatic chuck that uses the Coulomb force can be provided. On the other hand, in order to provide an electrostatic chuck using the Johnson Rahbeck force, the present invention may use alumina in which a transition metal element such as titanium and the like is added as a doping material.

The inner electrode 2 is preferred to be made of a mixture of tungsten carbide (WC) and alumina. Because the inner electrode 2 made of a mixture of tungsten carbide (WC) and alumina is excellently jointed with the ceramics member 4 made of alumina and the terminal 3, which are placed around the inner electrode 2, and cracks, such as boundary separation and the like, is not generated. Additionally, the diffusion and reaction of unnecessary conductive materials are prevented. The inner electrode 2 is preferred to be a printed electrode that is produced by applying the mixture paste of tungsten carbide (WC) powder and alumina powder on the ceramics member 4. The mixture of niobium carbide (NbC) and the alumina can be also used as the inner electrode 2′. The inner electrode 2 may be a mesh electrode or the like, other than the printed electrode.

The material quality of the terminal 3 may be equal to the material quality of the inner electrode 2, for similar reasons. In addition, Pt and Nb may be used. The terminal 3 is preferred to be tablet-shaped. Because the shaping of the tablet can make the manufacturing easy and can suppress breakage caused by a heating cycle and the like while keeping sufficient electric contact with both of the inner electrode 2 and the connection member 5.

The diameter of the terminal 3 and the inner diameter of the terminal hole 4c are preferred to be between about 0.7 mm and about 3 mm. In the case of 0.7 mm or less, since the joining (joint) area to the connection member 5 is small, it is difficult to maintain sufficient electrical conductivity. Also, in the case of 3 mm or more, the residual stress becomes excessively large.

As the method (style) of embedding the terminal 3, the tablet-shaped sinter obtained by sintering material powder having the foregoing composition is placed on the inner electrode 2. So as to cover the inner electrode 2 and the terminal 3, a green sheet made of the alumina powder or alumina is placed as baking material with alumina as a main component.

After that, a hot-press baking process is performed thereon, and the terminal 3 is consequently embedded. Other than the foregoing method, a method including molding the material mixture powder of the foregoing composition to the tablet shape and placing the material mixture powder molded in the tablet shape, and hot-press baking or using the paste-shaped material mixture powder may be used. From the viewpoint of not occurring cracks in the body having a junction and since the raw material is hard to diffuse, pre-manufactured sintered material is preferred for use in the terminal 3.

The inner diameter of the bore region 4a is preferred to be greater than the outer diameter of the connection member 5 because the connection member 5 is intended to be inserted into the bore region 4a. Also, a clearance 4d is intended to be formed between the surface of bore region 4a and the outer diameter of the connection member 5 so that the connection member 5 can thermally expand when the connection member 5 is inserted into the bore region 4a. The clearance 4d may be located around the entire circumference of the connection member 5, or a part of the connection member 5 may be in contact with the bore region 4a. The clearance 4d is preferred to be between 0 mm and about 0.5 mm when the outer diameter of the connection member 5 is assumed to be between about 4 and about 6 mm. If the clearance 4d is smaller than the lower limit value, the connection member 5 cannot be inserted into the bore region 4a, and this results in the very difficult situation when the manufacturing condition is considered. On the other hand, if the diameter of the bore region 4a is great, impurities are apt to intrude, which may lead to contamination and cause corrosion of an electrode. However, as the bore region 4a in the ceramics member 4 is larger, the strength of the ceramics member 4 is decreased. The bore region is also a guide when the connection member 5 is inserted therein. Thus, there is no need of providing the bore region 4a that is larger than necessary. Specifically, the diameter of the bore region 4a is preferred to be between about 3 and 15 mm. If the diameter is 3 mm or less, the junction area is small and the connection member 5 may be separated from the ceramics member 4 after being joined thereto. If the diameter is 15 mm or more, the residual stress becomes large, which may cause breakage.

On the bottom surface 4s of the bore region 4a, in order to widen the contact area with the solder junction layer 6, the bottom surface 4s is preferably made rough. Thus, the anchor effect improves the adhesive force between the bottom surface 4s of the bore region 4a and the solder junction layer 6. For this reason, the connection strength between the connection member 5 and the bottom surface 4s of the bore region 4a is improved. As for the bottom surface 4s of the bore region 4a, its surface roughness (Ra) is preferred to be between about 0.7 and about 2.0 μm, and more preferably be between about 1.0 and about 1.5 μm. When the surface roughness is about 0.7 μm or less, the anchor effect cannot be obtained and when the surface roughness is about 2.0 μm or more, the wetting property when the solder junction layer 6 is melted is decreased, which decreases the connection strength. The term [Anchor Effect] implies the mutual involvement between the solder junction layer 6 and the convex (bore) portion on the substrate surface, which is generated when the solder junction layer 6 invades the convex (bore) portion formed on the substrate surface. For example, in the first embodiment, this implies the mutual involvement between the solder junction layer 6 and the convex bore portion formed on the surface of the bottom surface 4s.

When the surface of the bottom surface 4s of the bore region 4a is made rough, the top surface 3s of the terminal 3 is preferably made rough at the same time.

According to the first embodiment, the ceramics member 4 including the surface of the bottom surface 4s of the bore region 4a being made rough (the surface roughness process) can improve the adhesive force between the solder junction layer 6 and the alumina ceramics member 4. The body having a junction that is used in the semiconductor supporting apparatus and the like. In particular, since the surface roughness process is performed so that the surface roughness of the bottom surface 4s is in the range of about Ra=0.7 to about 2.0 μm, the adhesive force to the solder junction layer 6 is improved.

As for the surface roughness process method, there is no special limitation. However, a sandblast method and the like are useable. As a condition of the sandblast method, this is preferred to be executed at an air pressure of about 2 kgf/cm² for about one minute, while using silicon carbide abrasion grains having a grain size of #600. With regard to the grain size distribution of the silicon carbide abrasion grain of the grain size #600, according to an electric resistance test method, the maximum grain diameter (dv−0 Value) is 53 μm or less, the grain diameter (dv−3 Value) of an accumulation height 3% point is 43 μm or less, and the grain diameter (dv−50 Value ) of an accumulation height 50% point is 20.0 μm±1.5 μm, and the grain diameter (dv−95 Value) of an accumulation height 95% point is 13 μm or more.

The solder junction layer 6 is filled between the lower end surface 5e of the end of the connection member 5 and the top surface 3s (exposure surface) of the terminal 3, as shown in FIG. 1A. As the material quality of the solder junction layer 6, indium and its alloy, aluminum and its alloy, gold and gold/nickel alloy may be used. In particular, the indium and aluminum alloy is desired from the viewpoint of the decrease in the residual stress. The solder junction layer 6 is preferred to be filled to cover the entire surface of the terminal 3 exposed to the bore region 4a, and the bottom surface 4s of the bore region 4a around it, and a part of the vicinity of the bottom surface of the wall surface.

The solder junction layer 6 is desired not to be filled in the clearance 4d of the bore region 4a. If the solder layer is filled in the clearance 4d, when there is a thermal expansion difference between the ceramics member 4 and the connection member 5, cracks may occur in the ceramics member 4. With regard to the thickness of the solder junction layer 6, when the diameter of the solder junction layer 6 is assumed to be between about 4 mm and about 6 mm, the film thickness of the solder junction layer 6 is preferred to be between about 0.05 mm and about 0.3 mm.

A spiral groove 5a is cut inside the connection member 5. Although illustration is omitted for the sake of easy understanding of the present invention, the end of the electrode having the spiral groove for supplying the electric power to the semiconductor susceptor 11 is screwed to the groove 5a.

When the main component of the ceramics member 4 is assumed to be alumina, it is preferred to use a material similar to the thermal expansion coefficient of the alumina for the connection member 5. Because the residual stress can be reduced. Specifically, the connection member 5 is preferred to be made of a conductive material having a thermal expansion coefficient is in the range between about 6.5 and about 9.5 ppm/K. This is to reduce the residual stress caused by the difference of the thermal expansion coefficient between the ceramics member 4 and the connection member 5. Also, this is because in the case of an electrostatic chuck with a heater, a RF susceptor and the like, it is possible to suppress breakage of the ceramics member 4, the connection member 5 and the joining portion between the ceramics member 4 and the connection member 5.

Also, the connection member 5 is preferred to be made of a metal having a thermal conductivity of about 50 W/mK or less. Although there is no special limit on the lower limit value of the thermal conductivity, it is about 20 W/mK.

If the material quality of the connection member 5 is defined as a metal having a thermal conductivity of 50 W/mK or less, the thermal uniformity of the junction between the connection member 5 and the solder junction layer 6 is improved. Specifically, the connection member 5 is preferred to be made of metals selected from the group of titanium (Ti), niobium (Nb), platinum (Pt) and the alloy thereof. In particular, titanium is preferable. Although the thermal expansion coefficient of the alumina is 8.0 ppm/K, with regard to the thermal expansion coefficients of Ti, Nb and Pt, Ti is 8.9, Nb is 7.2, and Pt is 9.0 [ppm/K], respectively.

The connection member 5 is preferred to be surface roughness processed such that the surface roughness of the contact portion with the solder junction layer 6 of the connection member 5 including the lower end surface 5e of the connection member 5 is in a range of Ra=about 1 to about 3 μm. The adhesive force to the solder junction layer 6 is further improved.

The foregoing sand blasting method is used for the surface roughness process. In addition to the sand blasting method, a stress suppression material is used in the connection member 5, and the surface roughness process is performed on the respective surfaces of the connection member 5 and the ceramics member 4 so that the connection strength between the connection member 5 and the ceramics member 4 can be further improved.

Among the first embodiment described above, the most preferable first embodiment is the body having a junction wherein the connection member includes a metal selected from a group consisting of Ti, Nb, Pt and alloys thereof;

the bottom surface of the bore region 4a is surface roughness processed so that a surface roughness thereof is in a range of Ra=about 0.7 to about 2.0 μm;

the lower end surface of the connection member 5 is made rough so that a surface roughness is in a range of Ra=about 1 to about 3 μm. The more preferable first embodiment further having the solder junction layer 6 made of indium (In) or aluminium (Al) alloy.

### Variation of First Embodiment

In the first embodiment, a plating layer is not formed. However, a plating layer including Ni may be formed between the bottom surface 4s of the bore region 4a and the terminal 3 and the solder junction layer 6. In addition to the process for roughing the top surface of the terminal 3 and the bottom surface 4s of the bore region 4a, the plating layer further improves the connection strength between the connection member 5 and the bottom surface 4s of the bore region 4a and the terminal 3. The plating layer preferably has a thermal expansion coefficient similar to the ceramics member 4, the terminal 3 and the connection member 5. Specifically, the plating layer preferably includes nickel (Ni) as the main component. As the sub-component of the plating layer, gold and/or titanium can be included.

The angle of the bottom surface 4s of the bore region 4a may be surface roughness processed so that the surface roughness is similar to Ra=about 0.1 to about 0.5 μm. This reduces the stress. In this case, when the surface roughness is less than Ra=0.1, it is easy to concentrate the stress, and when the surface roughness is greater than Ra=0.5, there is a case that the metal terminal goes up onto the angle.

(Method of Manufacturing Semiconductor Susceptor (Body having a Junction))

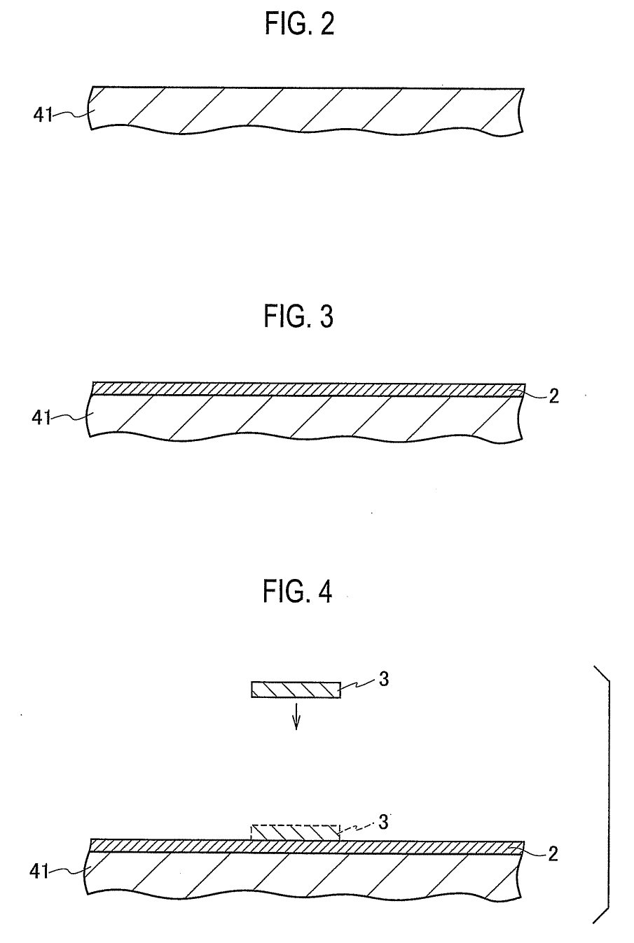

(1) A first ceramics layer 41 including alumina shown in FIG. 2 is prepared as a main component. Then, the surface of the first ceramics layer 41, which will serve as an electrode formation surface, is polished to a predetermined flatness.

(2) As shown in FIG. 3, the plate-shaped inner electrode 2 is formed on the top surface of the first ceramics layer 41. In this case, the electrode material paste is preferred to be printed on the surface of the first ceramics layer 41 and then dried to form a printed electrode.

(3) The electrode material paste of the same material as the inner electrode 2 is used to manufacture the tentative sinter in the shape of a tablet. After that, the described structure is baked at about 1800° C. in a nitrogen atmosphere for about two hours, to produce the sintered material terminal 3 having a density of 95% or more. Moreover, the terminal 3 is preferred to be machined to the shape of a predetermined dimensional disc (the shape of the tablet).

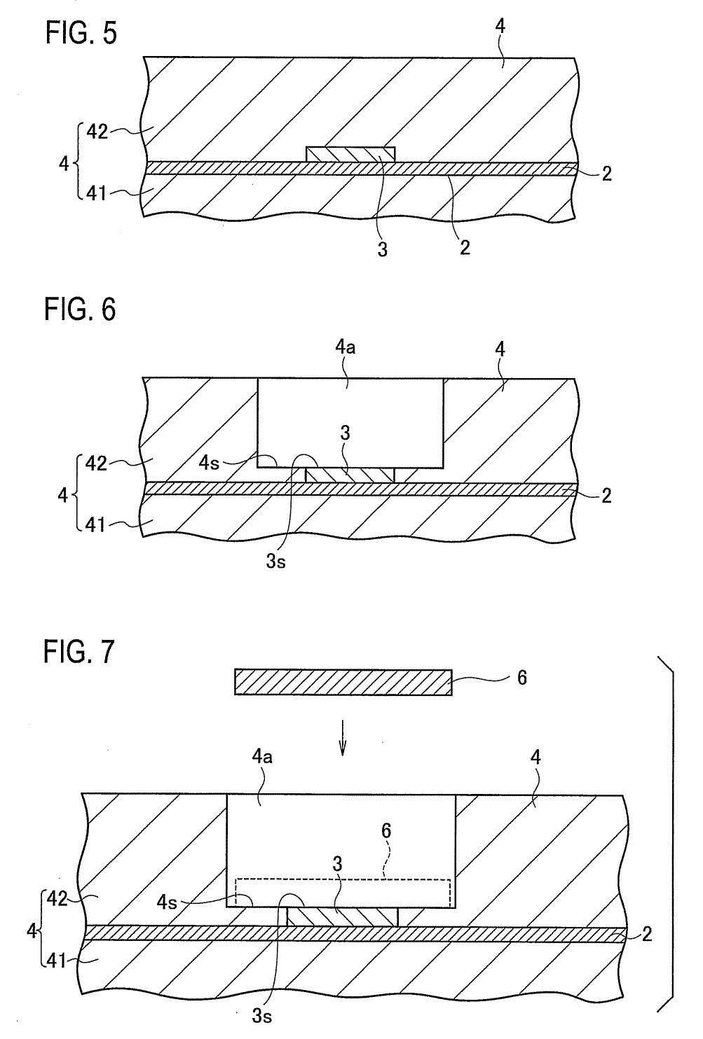

(4) As shown in FIG. 4, the terminal 3 is arranged on the inner electrode 2 so that the bottom surface is in contact with a part of the top surface of the inner electrode 2. After that, the first ceramics layer 41 on which the terminal 3 is arranged is placed inside a die. Then, a sintered material with a main component of alumina is arranged to cover the terminal 3 and the inner electrode 2. The die press is used to manufacture the molded body in which the inner electrode 2 and the terminal 3 are embedded. The molded body is hot-pressed and baked at 1850° C. in a nitrogen atmosphere, and a second ceramics layer 42 is obtained as shown in FIG. 5. Thus, the ceramics member 4 is manufactured in which the inner electrode 2 and the terminal 3 are embedded between the first ceramics layer 41 and the second ceramics layer 42. At this time, the terminal 3, the inner electrode 2 and the ceramics member 4 made of peripheral alumina are strongly sintered and joined.

(5) As shown in FIG. 6, the bore region 4a extending from the surface of the ceramics member 4 to the inner electrode 2 is formed, and the top surface 3s of the terminal 3 is exposed to the bottom surface 4s of the bore region 4a. At this time, the bore region 4a is preferred to be formed by a machining process. A part of the terminal 3 may be polished and machined so that the top surface 3s of the terminal 3 is exposed to the bottom surface 4s of the bore region 4a and then the bottom surface 4s of the bore region 4a is equal in height to the top surface 3c of the terminal 3.

(6) In order to increase the surface area of the bottom surface 4s of the bore region 4a, the surface roughness process of the bottom surface 4s is conducted by sandblasting. After that, the plating layer is formed on the bottom surface 4s of the bore region 4a and the top surface 3s of the terminal 3.

(7) As shown in FIG. 7, the solder junction layer 6 (solder material) is formed on the bottom surface 4s of the bore region 4a including the top surface 3a of the terminal 3.

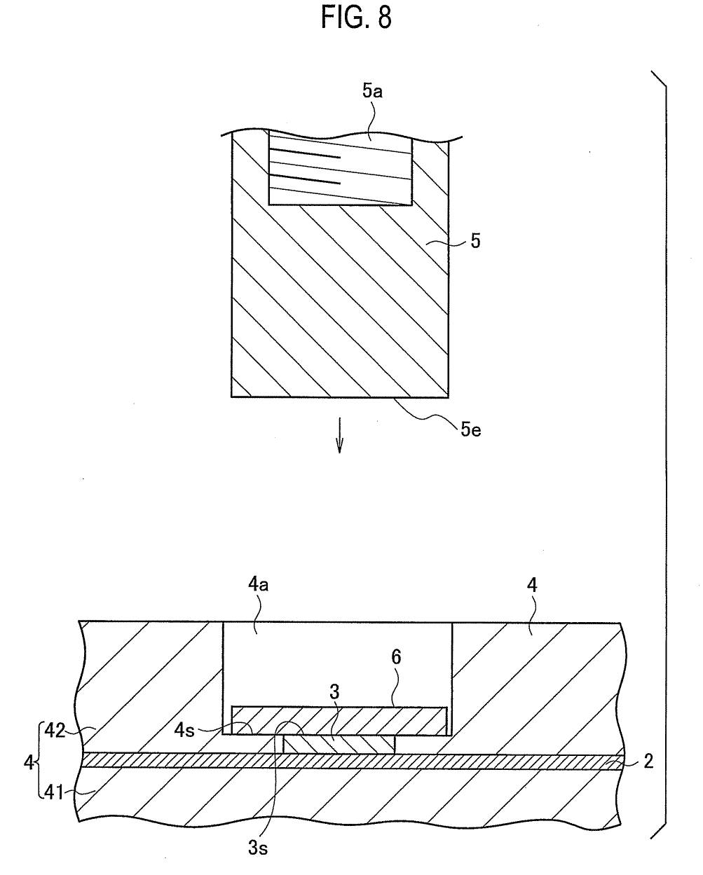

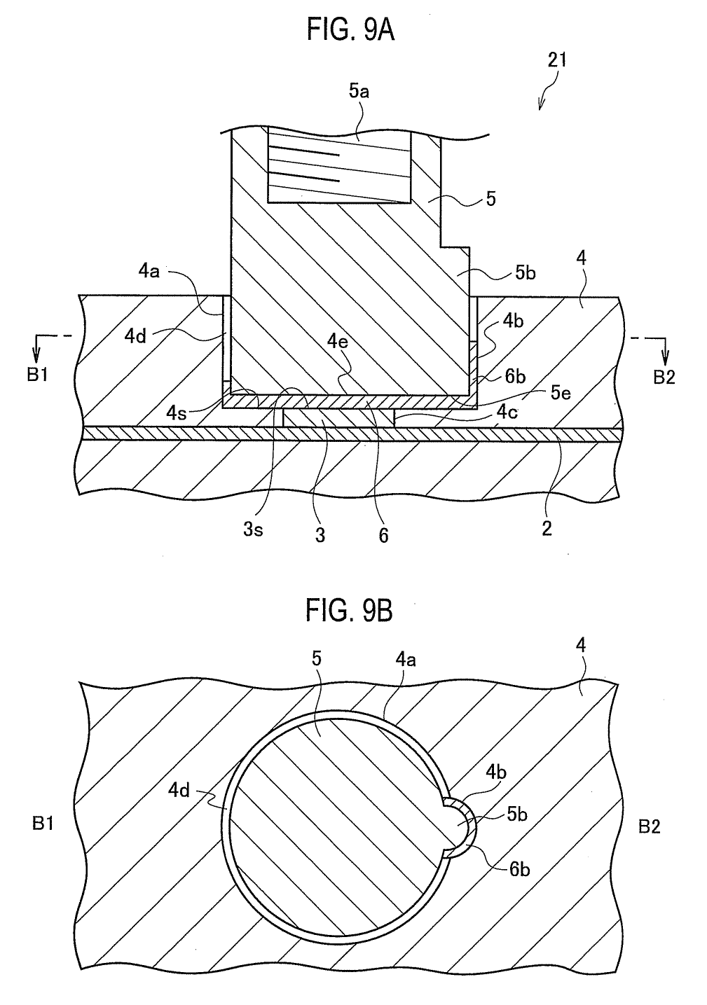

(8) As shown in FIG. 8, the low end surface 5e of the connection member 5 is in contact with the solder junction layer 6, and the lower portion of the connection member 5 is inserted into the bore region 4a. Before the connection member 5 is inserted into the bore region 4a, the contact surface with the solder junction layer 6 of the connection member 5, including the low end surface 5e of the connection member 5, may be subjected to the surface roughness process by using the sandblast method so that the surface roughness is in a range of Ra=about 1 to about 3 μm. After that, either under vacuum or an inert atmosphere, the solder junction layer 6 is heated and melted. Preferably, the heating temperature, in the case of the indium solder, is about 2000° C., and in the case of the aluminum (Al) alloy solder, it is heated to about 670° C., and in the case of the gold solder, it is heated to about 1000° C. After the solder junction layer 6 is melted, the solder junction layer 6 is maintained at the same temperature for about 5 minutes. Then, the heating is stopped and natural cooling occurs. The connection member 5 is connected through the solder junction layer 6 to the terminal 3. As discussed above, the semiconductor susceptor 11 is manufactured as shown in FIGS. 1A, 1B.

### Second Embodiment

### Semiconductor Susceptor

### (Body Having a Junction)

The difference from the semiconductor susceptor 11 according to the first embodiment will be described.

As to the semiconductor susceptor 21 according to the second embodiment shown in FIG. 9A, on the section of the ceramics member 4 parallel to the surface thereof, as shown in FIG. 9B, a semi-circular solder retaining space 4b is provided on a part of the side wall of the bore region 4a in the ceramics member 4, and a solder junction layer 6b is filled in a part of a solder retaining space 4b. The semiconductor susceptor 21 further includes a semi-circular key portion 5b, which is engaged with the solder retaining space 4b, on a part of the outer circumferential surface of the connection member 5 so that the connection member 5 is embedded in a part of the solder retaining space 4b.

Since the semiconductor susceptor 21 according to the second embodiment includes the solder retaining space 4b in a part of the clearance 4d, the solder junction layer 6 that fills the space functions as a key (hereafter, referred to as “Key Effect”). Thus, as compared with the first embodiment without the solder retaining space 4b, the torsional rupture strength opposing the rotational force, with the axis of the connection member 5 as the center, is very high.

According to the second embodiment, only a part of the clearance 4d is filled with the solder junction layer 6. Thus, the connection member 5 and the ceramics member 4 are strongly connected on only a part of the side of the bore region 4a, and the clearance 4d is mainly generated between the connection member 5 and the ceramics member 4. Hence, the breakage of the ceramics member 4 that is generated when the solder junction layer 6 is filled in the entirety of the clearance 4d is never generated in the second embodiment. The second embodiment has a torsion rupture strength that is very high as compared with the first embodiment in which the connection member 5 having a sectional shape similar to that of the bore region 4a is used as shown in FIG. 1.

As described in the first embodiment, when using the connection member 5 having a sectional shape similar to that of the bore region 4a, the clearance 4d is generated between the bore region 4a and the connection member 5. The connection member 5 may be in contact with part of the bore region 4a.

However, depending on the torsion direction of the connection member 5, the clearance 4d is always generated. Thus, there is a tendency that the member 5 is broken when the torsion direction is inverted. On the other hand, the second embodiment is designed such that, even if the screw in the groove 5a of the connection member 5 is tightened or unscrewed, the solder junction layer 6b is filled such that the clearance 4d is not generated in the semi-circular solder retaining space 4b in both of the torsion directions. Hence, the key effect exhibits a high torsion rupture strength.

The solder junction layer 6 is preferred to be formed to go up the side of the connection member 5, for a distance of about 2 mm from the bottom surface 4s of the bore region 4a: Consequently, the joint area between the connection member 5 and the solder junction layer 6 is increased, which can improve the joint strength. Specifically, the wall surface of the bore region 4a is surface-processed by using a metalizing process and the like, and as shown in FIG. 9A, the solder junction layer 6b is preferred extends up the wall surface of the bore region 4a. This is advantageous in that the contact area between the solder junction layer 6 and the connection member 5 and the bore region 4a is increased which improves the joint strength. In this case, in addition to the fact that the metalizing process is performed on the part of the side of the bore region 4a, a surface oxidizing process is preferred to be performed on a predetermined portion of the connection member 5 onto which the solder junction layer 6 does not contact. This is because, since the surface oxidizing process prevents the solder junction layer 6 from extending up, the entire clearance 4d can be protected from being filled in by the solder junction layer 6. Not only the surface oxidizing process, but also other process can be used. For example, a coating a material having poor wetting property may be applied to the portion where the solder junction layer 6 is not desired to go up. When one or both of the metalizing process to the ceramics member 4 and the surface oxidizing process to the connection member 5 are performed, the solder junction layer 6b extends only to the solder retaining space 4b.

Although the solder retaining space 4b may be provided at one position, a plurality of solder retaining spaces 4b may be provided. This is because, when the solder retaining spaces 4b are arranged at, for example, two or four positions so that they are symmetrical with each other, the torsional rupture strength is increased. However, a structure with five or more spaces is not preferred because the amount of the solder junction materials is increased, and the possibility that breakage occurs in the ceramics is increased. In particular, one set or two sets of the solder retaining spaces 4b are preferred to be provided at a positions opposite to each other on the side wall of the bore region 4a. Most preferably, one set is installed at a positions opposite to each other on the side wall of the bore region 4a.

### (Method of Manufacturing Semiconductor Susceptor)

The method of manufacturing the semiconductor susceptor 21 according to the second embodiment will be described below with the difference from the first embodiment as the center.

(1) The ceramics member 4 is machined similarly to FIG. 2 through FIG. 6 in the first embodiment.

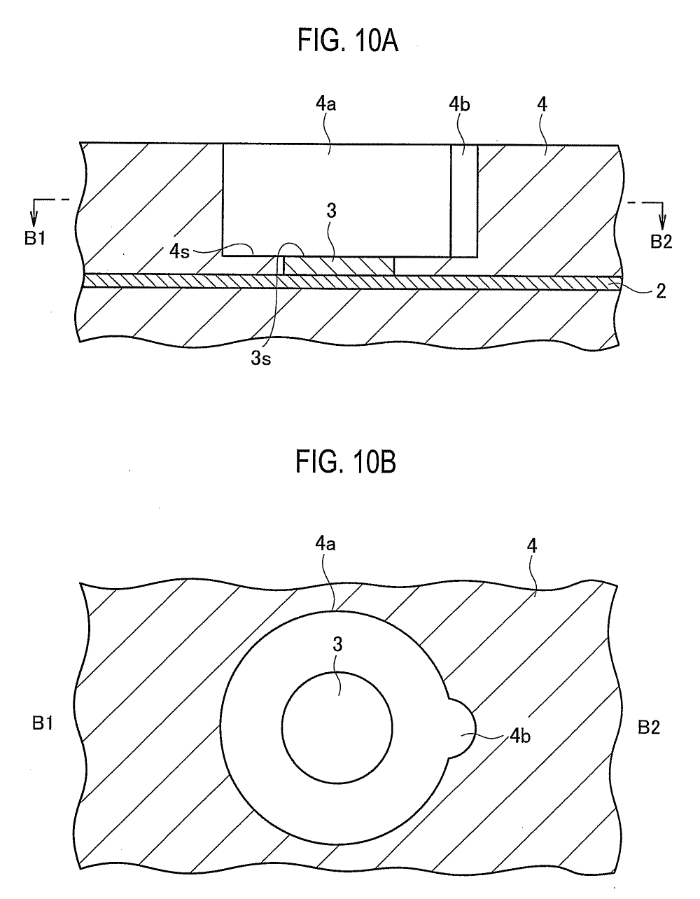

(2) As shown in FIGS. 10A, 10B, a drill or the like is used to form the solder retaining space 4b in a part of the outer circumference of the bore region 4a in the ceramics member 4. At that time, the solder retaining space 4b may be formed simultaneously with the bore region 4a.

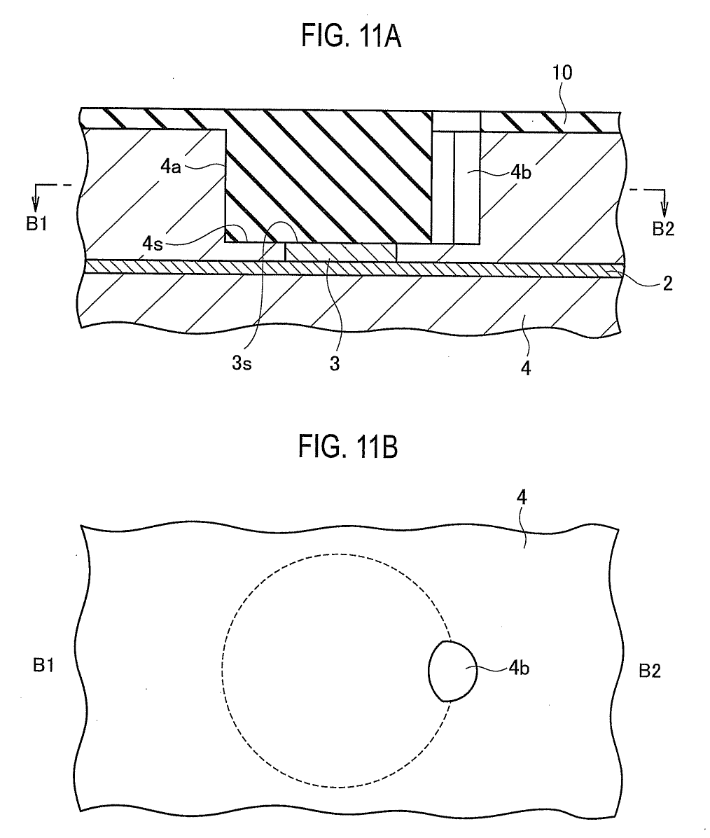

(3) After that, as shown in FIGS. 11A, 11B, except for the solder retaining space 4b, a sealing member 10 is placed on the ceramics member 4, and the metalizing process is executed. This is because the execution of the metalizing process causes the solder junction layer 6 to easily run into the solder retaining space 4b when the solder is melted. The surface oxidizing process is performed on a predetermined portion of the connection member 5 where the solder junction layer 6 is not permitted.

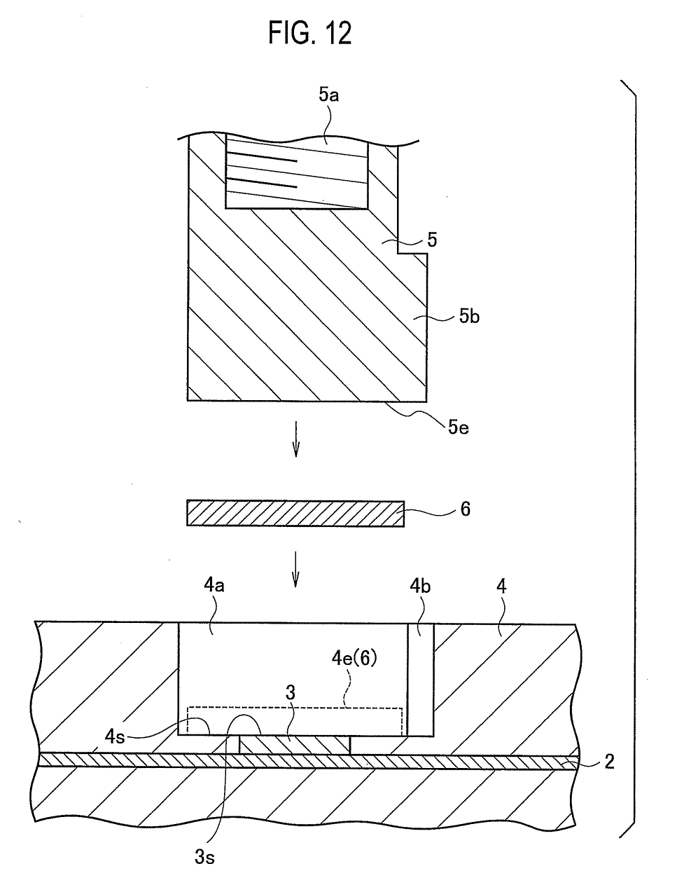

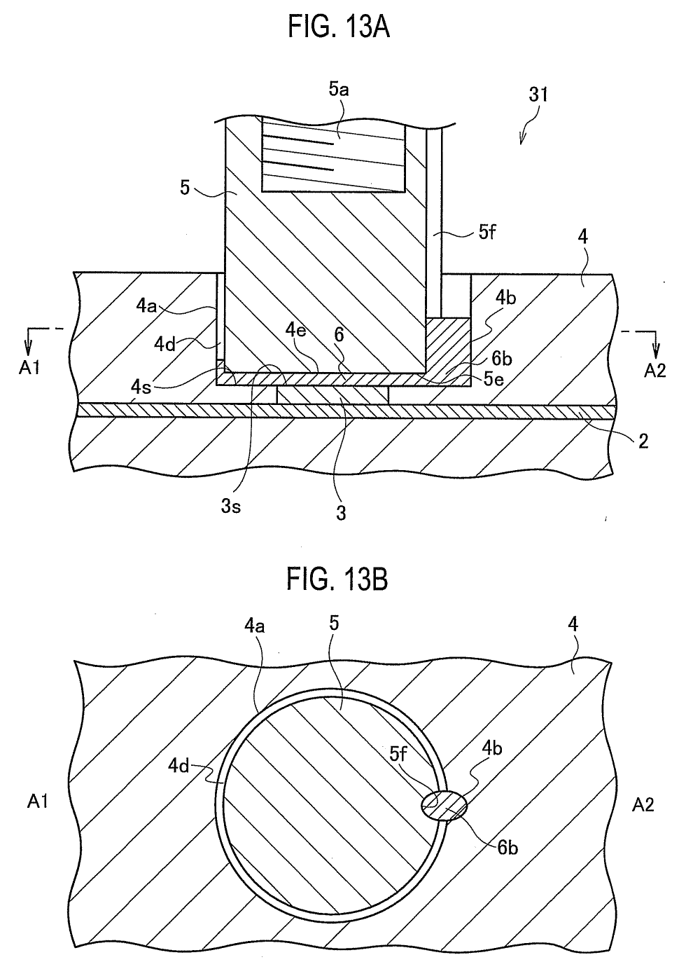

(4) As shown in FIG. 12, the solder junction layer 6 is arranged in a first space 4e on the terminal 3. Then, through the solder junction layer 6, the connection member 5 is arranged inside the bore region 4a in the ceramics member 4. The connection member 5 is made of a metal having a high melting point and a thermal expansion coefficient similar to that of the ceramics member 4. The member 5 is inserted into the bore region 4a so as to contact the solder junction layer 6. After that, the solder junction layer 6 is heated and melted. The heating temperature is preferred to be higher by about 20° C. than the melting point of the solder junction layer 6. After confirming that the solder junction layer 6 is melted, the solder junction layer 6 is placed at that temperature for about five minutes.

(5) Then, since the solder junction layer 6 has melted onto the side of the connection member 5 and the side of the solder retaining space 4b, the boundary of the solder junction layer 6 is raised to a predetermined height, and the solder retaining space 4b is filled. After that, the heating is stopped and natural cooling occurs. The connection member 5 is connected through the solder junction layer 6 to the terminal 3. As discussed above, the semiconductor susceptor 21 shown in FIGS. 9A, 9B is manufactured.

According to the second embodiment, the junction structure is provided, which is highly reliable when the external spiral portion is attached or removed and which can be used at high temperature.

### Variation of Embodiment

As discussed above, the present invention has been described by using the first and second embodiments. However, the discussions and drawings that constitute the part of this disclosure should not be understood to limit the present invention. From this disclosure, the various variation embodiments, examples and operational techniques would be evident for one skilled in the art. For example, in order to increase the torsional rupture strength, the following configuration may be employed.

Variation 1: As shown in FIGS. 13A, 13B, it is possible to use a semiconductor susceptor 31 designed such that the connection member 5 has a notch 5f on the inside on a part of the external circumferential surface of the connection member 5. When the member 5 is attached to the ceramics member 4, the solder junction layer 6 fills in a part of the notch 5f extending to the first space 4e.

In this way, the present invention naturally includes various embodiments that are not described here. Thus, the technical range of the present invention is determined only in accordance with the invention as described in the specification

### EXAMPLE

### Manufacturing Example of Body having a Junction

Examples 1-42 and comparative examples 1-68 of the body having a junction shown in FIGS. 1A, 1B were manufactured under the conditions described on the tables 1,2,3, in accordance with the method of manufacturing the first embodiment of the body having a junction.

(1) The first ceramics layer 41 produced from alumina powder of 99.9 mass % was prepared as shown in FIG. 2.

(2) As shown in FIG. 3, the electrode material paste made of a mixture of tungsten carbide (WC) and alumina (Al₂O₃) was printed on the top surface of the first ceramics layer 41 and dried to then form the printed electrode, namely, the plate-shaped inner electrode 2.

(3) The tungsten carbide (WC) powder and the alumina (Al₂O₃) powder were mixed, and after it was molded, it was baked at 1700° C. in an inert atmosphere, and a sintered material was obtained. From this, the tablet-shaped terminal 3 having a diameter of about 2 mm and a thickness of about 1 mm was machined and cut.

(4) As shown in FIG. 4, the terminal 3 was arranged on the inner electrode 2 so that the bottom surface was in contact with a part of the top surface of the inner electrode 2. After that, the first ceramics layer 41 in which the terminal 3 was arranged was placed inside a die. Then, the raw material powder with alumina as a main component was provided to cover the terminal 3 and the inner electrode 2. The die press was used to manufacture the molded body in which the inner electrode 2 and the terminal 3 were embedded in the alumina raw material powder. The molded body was hot-pressed and baked at 170° C. in a nitrogen atmosphere, and the ceramics member 4 was obtained as shown in FIG. 5.

(5) As shown in FIG. 6, the bore region 4a extending to the terminal 3 and having a diameter of about 7 mm and a depth of about 4 mm was provided by a machining process.

The terminal 3 was thus exposed to the bottom surface 4s of the bore region 4a so that the bottom surface 4s and the top surface 3s of the terminal 3 were equal in height. Part of the terminal 3 was polished simultaneously with the bore region 4a.

(6) The bottom surface 4s of the bore region 4a and the lower end surface 5e of the connection member 5 were surface roughness processed by sandblasting at an air pressure 2 kgf/cm², while using silicon carbide abrasion grain of a grain size #600 so as to proved a surface roughness (Ra) shown on a table 1 and a table 2. The surface roughness was adjusted by changing the sandblast time. For example, the surface roughness (Ra) on the bottom surface 4s of the bore region 4a was 0.3 μm when the sandblast was not used, and the Ra was 0.7 μm when the sandblast time was set at 30 seconds, and the Ra was 2.5 μm when the sandblast time was set at five minutes.

(7) Next, the Ni plating was performed on the bore region 4a at a plating temperature of 70° C. for ten minutes, by using an electroless plating method. After cleaning and drying, as shown in FIG. 7, the solder junction layer 6 (solder material) was formed on the bottom surface 4s of the bore region 4a including the top surface 3a of the terminal 3.

In succession, when the solder junction layer 6 was made of indium (In), the step (9) was performed, and when the solder junction layer 6 was made of aluminum (Al) alloy, the step (10) was performed.

(8) When the solder junction layer 6 was made of indium (In), the connection member 5 having the material quality shown on the table 1 and the table 2 and the ceramics member 4 were heated at 180° C. Also, a supersonic soldering iron was used to melt the solder junction layer 6, and the bottom surface 4s of the bore region 4a and the Ni plating layer on the top surface 3s were wetted in the solder junction layer 6. After that, as shown in FIG. 8, the lower portion of the connection member 5 was inserted into the bore region 4a so that the lower end surface 5e of the connection member 5 contacted the solder junction layer 6. Then, a weight of 200 g was used to apply a load to the connection member, while being cooled to a room temperature.

(9) When the solder junction layer 6 was made of aluminum (Al) alloy, as shown in FIG. 8, the connection member 5 having the material quality shown on the table 2 was inserted into the bore region 4a so that the lower end surface 5e of the connection member 5 contacted the solder junction layer 6. Then, while the weight of 200 g was used to apply a load, the joining process was performed in a vacuum furnace at 610° C. in a vacuum pressure of 110⁻⁵ Torr. Then, the connection member 5 and the ceramics member 4 were joined through the solder junction layer 6. Consequently, the body having a junction having the solder junction layer 6 was provided on the surface of the terminal 3, as shown in FIGS. 1A, 1B.

In the connection member of the tables 1, 2, the purities of Ti, Nb, Pt and Mo were 95% or more, and the Ti—Ni alloy was Ti—Ni=50:50 (at weight. %).

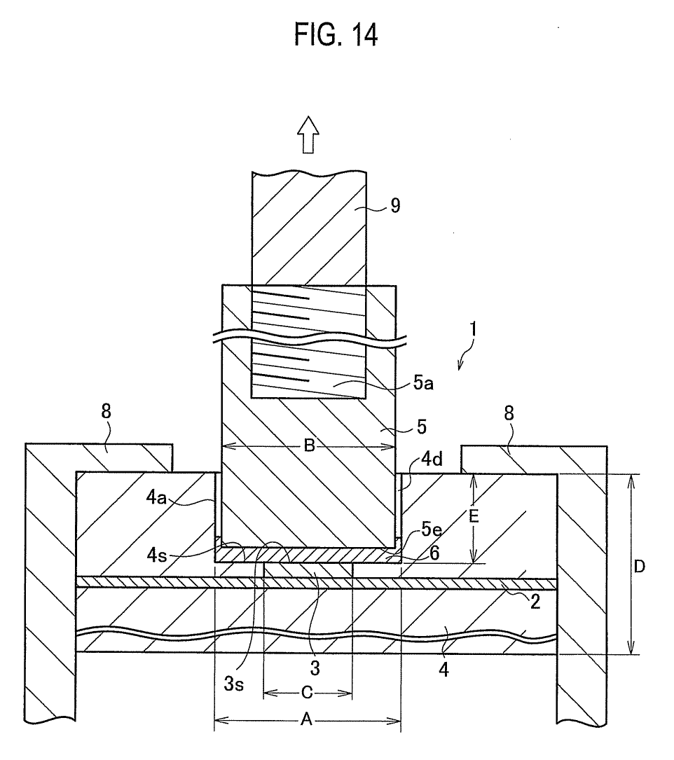

As discussed above, a plurality of junction structure bodies 1 (test pieces) were prepared as shown in FIG. 14. In each piece, a dimension of the ceramics member 4 was 20 mm×20 mm, a thickness D of the ceramics member 4 was 5 mm, a diameter A of the bore region 4a was 7 mm, a depth E of the bore region 4a was 4 mm, a diameter C of the terminal 3 was 3 mm, and a thickness of the terminal 3 was 0.5 mm. Each of the junction structure bodies was composed of the terminal material quality and the solder junction layer, as shown in the table 1, the table 2, and the table 3, and has an alumina surface roughness Ra and a terminal surface roughness Ra.

### (Joint Strength Measurement)

After the body having a junction 1 was put between a fixing tool 8, a pulling member 9 that was screwed into the groove 5a in the connection member 5 was used to apply a load vertically. The load resistance was measured until the connection member 5 separated from the ceramics member 4. This measurement defined the joint strength (kgf). The experiment conditions and the experiment results are collectively shown in the table 1, the table 2, and the table 3.

TABLE 1

| | SURFACE | SURFACE | | | |
|---|---|---|---|---|---|
| | ROUGHNESS OF | ROUGHNESS OF | MATERIAL OF | SOLDER | |
| | BOTTOM SURFACE | CONNECTION | CONNECTION | JUNCTION | JOINT |
| No. | OF BORE Ra(um) | MEMBER Ra(um) | MEMBER | LAYER | STRENGTH(kgf) |
| EXAMPLE 1 | 0.7 | 1.0 | Ti | In | 32.4 |
| EXAMPLE 2 | 0.7 | 2.1 | Ti | In | 31.5 |
| EXAMPLE 3 | 0.7 | 3.0 | Ti | In | 31.5 |
| EXAMPLE 4 | 1.0 | 1.0 | Ti | In | 37.5 |
| EXAMPLE 5 | 1.0 | 2.1 | Ti | In | 38.5 |
| EXAMPLE 6 | 1.0 | 3.0 | Ti | In | 32.3 |
| EXAMPLE 7 | 1.5 | 2.1 | Ti | In | 39.5 |
| EXAMPLE 8 | 2.0 | 2.1 | Ti | In | 42.3 |
| EXAMPLE 9 | 2.0 | 1.0 | Ti | In | 40.4 |
| EXAMPLE 10 | 2.0 | 3.0 | Ti | In | 41.6 |
| EXAMPLE 11 | 0.7 | 2.2 | Nb | In | 33.4 |
| EXAMPLE 12 | 1.0 | 2.2 | Nb | In | 35.7 |
| EXAMPLE 13 | 1.5 | 1.9 | Nb | In | 36.7 |
| EXAMPLE 14 | 2.0 | 2.1 | Nb | In | 41.6 |
| EXAMPLE 15 | 0.7 | 2.1 | Pt | In | 32.3 |
| EXAMPLE 16 | 1.0 | 2.3 | Pt | In | 38.4 |
| EXAMPLE 17 | 1.5 | 2.1 | Pt | In | 38.2 |
| EXAMPLE 18 | 2.0 | 2.3 | Pt | In | 40.6 |
| EXAMPLE 19 | 0.7 | 2.3 | Ti—Ni alloy | In | 30.6 |
| EXAMPLE 20 | 1.0 | 2.1 | Ti—Ni alloy | In | 35.0 |
| EXAMPLE 21 | 1.5 | 2.0 | Ti—Ni alloy | In | 35.2 |
| EXAMPLE 22 | 2.0 | 2.2 | Ti—Ni alloy | In | 40.6 |
| EXAMPLE 23 | 0.7 | 1.0 | Ti | Al alloy | 52.4 |
| EXAMPLE 24 | 0.7 | 2.2 | Ti | Al alloy | 52.3 |
| EXAMPLE 25 | 0.7 | 3.0 | Ti | Al alloy | 49.6 |
| EXAMPLE 26 | 1.0 | 1.8 | Ti | Al alloy | 61.3 |
| EXAMPLE 27 | 1.5 | 1.6 | Ti | Al alloy | 60.2 |
| EXAMPLE 28 | 2.0 | 2.1 | Ti | Al alloy | 55.4 |
| EXAMPLE 29 | 2.0 | 1.0 | Ti | Al alloy | 44.6 |
| EXAMPLE 30 | 2.0 | 3.0 | Ti | Al alloy | 42.6 |
| EXAMPLE 31 | 0.7 | 2.4 | Nb | Al alloy | 54.3 |
| EXAMPLE 32 | 1.0 | 2.1 | Nb | Al alloy | 60.5 |
| EXAMPLE 33 | 1.5 | 2.3 | Nb | Al alloy | 64.2 |
| EXAMPLE 34 | 2.0 | 2.5 | Nb | Al alloy | 52.1 |
| EXAMPLE 35 | 0.7 | 2.1 | Pt | Al alloy | 51.2 |
| EXAMPLE 36 | 1.0 | 2.0 | Pt | Al alloy | 55.6 |
| EXAMPLE 37 | 1.5 | 2.0 | Pt | Al alloy | 59.8 |
| EXAMPLE 38 | 2.0 | 2.1 | Pt | Al alloy | 58.3 |
| EXAMPLE 39 | 0.7 | 2.6 | Ti—Ni alloy | Al alloy | 49.5 |
| EXAMPLE 40 | 1.0 | 1.8 | Ti—Ni alloy | Al alloy | 53.4 |
| EXAMPLE 41 | 1.5 | 2.6 | Ti—Ni alloy | Al alloy | 59.2 |
| EXAMPLE 42 | 2.0 | 2.4 | Ti—Ni alloy | Al alloy | 45.2 |

TABLE 2

| | SURFACE | SURFACE | | | |
|---|---|---|---|---|---|
| | ROUGHNESS OF | ROUGHNESS OF | MATERIAL OF | SOLDER | |
| | BOTTOM SURFACE | CONNECTION | CONNECTION | JUNCTION | JOINT |
| No. | OF BORE Ra(um) | MEMBER Ra(um) | MEMBER | LAYER | STRENGTH(kgf) |
| COMPARATIVE EXAMPLE 1 | 0.7 | 0.9 | Ti | In | 11.8 |
| COMPARATIVE EXAMPLE 2 | 0.7 | 3.1 | Ti | In | 10.4 |
| COMPARATIVE EXAMPLE 3 | 2.0 | 0.9 | Ti | In | 10.3 |
| COMPARATIVE EXAMPLE 4 | 2.0 | 3.1 | Ti | In | 9.8 |
| COMPARATIVE EXAMPLE 5 | 0.6 | 1.0 | Ti | In | 10.3 |
| COMPARATIVE EXAMPLE 6 | 2.1 | 1.0 | Ti | In | 9.6 |
| COMPARATIVE EXAMPLE 7 | 0.6 | 3.0 | Ti | In | 10.2 |
| COMPARATIVE EXAMPLE 8 | 2.1 | 3.0 | Ti | In | 10.8 |
| COMPARATIVE EXAMPLE 9 | 0.7 | 0.9 | Nb | In | 10.2 |
| COMPARATIVE EXAMPLE 10 | 0.7 | 3.1 | Nb | In | 11.2 |
| COMPARATIVE EXAMPLE 11 | 2.0 | 0.9 | Nb | In | 10.8 |
| COMPARATIVE EXAMPLE 12 | 2.0 | 3.1 | Nb | In | 10.2 |
| COMPARATIVE EXAMPLE 13 | 0.6 | 1.0 | Nb | In | 9.6 |
| COMPARATIVE EXAMPLE 14 | 2.1 | 1.0 | Nb | In | 8.2 |
| COMPARATIVE EXAMPLE 15 | 0.6 | 3.0 | Nb | In | 6.4 |
| COMPARATIVE EXAMPLE 16 | 2.1 | 3.0 | Nb | In | 10.4 |
| COMPARATIVE EXAMPLE 17 | 0.7 | 0.9 | Pt | In | 8.8 |
| COMPARATIVE EXAMPLE 18 | 0.7 | 3.1 | Pt | In | 10.2 |
| COMPARATIVE EXAMPLE 19 | 2.0 | 0.9 | Pt | In | 4.4 |
| COMPARATIVE EXAMPLE 20 | 2.0 | 3.1 | Pt | In | 6.6 |
| COMPARATIVE EXAMPLE 21 | 0.6 | 1.0 | Pt | In | 8.4 |
| COMPARATIVE EXAMPLE 22 | 2.1 | 1.0 | Pt | In | 10.2 |
| COMPARATIVE EXAMPLE 23 | 0.6 | 3.0 | Pt | In | 8.2 |
| COMPARATIVE EXAMPLE 24 | 2.1 | 3.0 | Pt | In | 7.4 |
| COMPARATIVE EXAMPLE 25 | 0.7 | 0.9 | Ti—Ni alloy | In | 10.2 |
| COMPARATIVE EXAMPLE 26 | 0.7 | 3.1 | Ti—Ni alloy | In | 9.2 |
| COMPARATIVE EXAMPLE 27 | 2.0 | 0.9 | Ti—Ni alloy | In | 10.3 |
| COMPARATIVE EXAMPLE 28 | 2.0 | 3.1 | Ti—Ni alloy | In | 11.4 |
| COMPARATIVE EXAMPLE 29 | 0.6 | 1.0 | Ti—Ni alloy | In | 12 |
| COMPARATIVE EXAMPLE 30 | 2.1 | 1.0 | Ti—Ni alloy | In | 10.2 |
| COMPARATIVE EXAMPLE 31 | 0.6 | 3.0 | Ti—Ni alloy | In | 8.8 |
| COMPARATIVE EXAMPLE 32 | 2.1 | 3.0 | Ti—Ni alloy | In | 9.2 |
| COMPARATIVE EXAMPLE 33 | 1.0 | 2.2 | Mo | In | 7.5 |
| COMPARATIVE EXAMPLE 34 | 1.0 | 2.1 | SUS304 | In | 0.5 |

TABLE 3

| | SURFACE | SURFACE | | | |
|---|---|---|---|---|---|
| | ROUGHNESS OF | ROUGHNESS OF | MATERIAL OF | SOLDER | |
| | BOTTOM SURFACE | CONNECTION | CONNECTION | JUNCTION | JOINT |
| No. | OF BORE Ra(um) | MEMBER Ra(um) | MEMBER | LAYER | STRENGTH(kgf) |
| COMPARATIVE EXAMPLE 35 | 0.7 | 0.9 | Ti | Al alloy | 12.5 |
| COMPARATIVE EXAMPLE 36 | 0.7 | 3.1 | Ti | Al alloy | 12.6 |
| COMPARATIVE EXAMPLE 37 | 2.0 | 0.9 | Ti | Al alloy | 13.1 |
| COMPARATIVE EXAMPLE 38 | 2.0 | 3.1 | Ti | Al alloy | 12.2 |
| COMPARATIVE EXAMPLE 39 | 0.6 | 1.0 | Ti | Al alloy | 13.2 |
| COMPARATIVE EXAMPLE 40 | 2.1 | 1.0 | Ti | Al alloy | 11.3 |
| COMPARATIVE EXAMPLE 41 | 0.6 | 3.0 | Ti | Al alloy | 12.5 |
| COMPARATIVE EXAMPLE 42 | 2.1 | 3.0 | Ti | Al alloy | 11.8 |
| COMPARATIVE EXAMPLE 43 | 0.7 | 0.9 | Nb | Al alloy | 13.2 |
| COMPARATIVE EXAMPLE 44 | 0.7 | 3.1 | Nb | Al alloy | 12.2 |
| COMPARATIVE EXAMPLE 45 | 2.0 | 0.9 | Nb | Al alloy | 13.4 |
| COMPARATIVE EXAMPLE 46 | 2.0 | 3.1 | Nb | Al alloy | 12.4 |
| COMPARATIVE EXAMPLE 47 | 0.6 | 1.0 | Nb | Al alloy | 11.8 |
| COMPARATIVE EXAMPLE 48 | 2.1 | 1.0 | Nb | Al alloy | 12.6 |
| COMPARATIVE EXAMPLE 49 | 0.6 | 3.0 | Nb | Al alloy | 11.8 |
| COMPARATIVE EXAMPLE 50 | 2.1 | 3.0 | Nb | Al alloy | 10.9 |
| COMPARATIVE EXAMPLE 51 | 0.7 | 0.9 | Pt | Al alloy | 10.4 |
| COMPARATIVE EXAMPLE 52 | 0.7 | 3.1 | Pt | Al alloy | 11.6 |
| COMPARATIVE EXAMPLE 53 | 2.0 | 0.9 | Pt | Al alloy | 12.2 |
| COMPARATIVE EXAMPLE 54 | 2.0 | 3.1 | Pt | Al alloy | 13.3 |
| COMPARATIVE EXAMPLE 55 | 0.6 | 1.0 | Pt | Al alloy | 11.4 |
| COMPARATIVE EXAMPLE 56 | 2.1 | 1.0 | Pt | Al alloy | 11.8 |
| COMPARATIVE EXAMPLE 57 | 0.6 | 3.0 | Pt | Al alloy | 12.3 |
| COMPARATIVE EXAMPLE 58 | 2.1 | 3.0 | Pt | Al alloy | 11.4 |
| COMPARATIVE EXAMPLE 59 | 0.7 | 0.9 | Ti—Ni alloy | Al alloy | 11.6 |
| COMPARATIVE EXAMPLE 60 | 0.7 | 3.1 | Ti—Ni alloy | Al alloy | 12.2 |
| COMPARATIVE EXAMPLE 61 | 2.0 | 0.9 | Ti—Ni alloy | Al alloy | 13.2 |
| COMPARATIVE EXAMPLE 62 | 2.0 | 3.1 | Ti—Ni alloy | Al alloy | 12.4 |
| COMPARATIVE EXAMPLE 63 | 0.6 | 1.0 | Ti—Ni alloy | Al alloy | 12.2 |
| COMPARATIVE EXAMPLE 64 | 2.1 | 1.0 | Ti—Ni alloy | Al alloy | 12.4 |
| COMPARATIVE EXAMPLE 65 | 0.6 | 3.0 | Ti—Ni alloy | Al alloy | 13.5 |
| COMPARATIVE EXAMPLE 66 | 2.1 | 3.0 | Ti—Ni alloy | Al alloy | 12.5 |
| COMPARATIVE EXAMPLE 67 | 1.0 | 2.3 | Mo | Al alloy | 6.3 |
| COMPARATIVE EXAMPLE 68 | 1.0 | 2.2 | SUS304 | Al alloy | 2.2 |

From the table 1, an excellent joint strength was obtained when the surface roughness Ra of the bottom surface 4s in the bore region 4a was between about 0.7 μm and about 2.0 μm. In particular, an excellent connection strength was achieved as the surface roughness Ra of the bottom surface 4s approached 2.0 μm.

As shown in the examples 1 to 10 on the table 1 and the comparative examples 1-8 on the table 2, when the solder junction layer was made of indium (In), and conductive connection member materials were titanium (Ti), excellent joint strength was obtained when the surface roughness Ra of the bottom surface 4s of bore region 4a=0.7 μm to 2.0 μm, and the surface roughness Ra of the surface of conductive connection member=1.0 μm to 3.0 μm. From these results, critical range of the surface roughness Ra of the bottom surface 4s of bore region 4a, and the surface roughness Ra of the surface of conductive connection member became clear.

As the same manner, as shown in the table 1 and the table 2, when the solder junction layer was made of indium (In), the critical range of the surface roughness Ra of the bottom surface 4s of bore region 4a, and the surface roughness Ra of the surface of conductive connection member became clear by the following examples and comparative examples:

the examples 11 to 14 and the comparative, examples 9-16 where the conductive connection member materials were niobium (Nb);

the examples 15 to 18 and the comparative examples 17-24 where the conductive connection member materials were platinum (Pt);

the examples 19 to 22 and the comparative examples 25-32 where the conductive connection member materials were Ti—Ni alloy.

As shown on the table 2, when the solder junction layer was made of indium (In), it was found that comparative examples 33, 34, where the conductive connection member materials were molybdenum (Mo) or stainless steel (SUS304), and both the surface roughness Ra of the bottom surface 4s of bore region 4a and the surface roughness Ra of the surface of conductive connection member were in the range of the claimed invention were inferior in the joint strength. From these results, Ti, Nb, Pt, Ti—Ni alloy were preferable as conductive connection member materials.

As shown in the examples 23 to 30 on the table 1 and the comparative examples 35-42 on the table 2, when the solder junction layer was made of aluminum (Al), and conductive connection member materials were titanium (Ti), excellent joint strength was obtained when the surface roughness Ra of the bottom surface 4s of bore region 4a=0.7 μm to 2.0 μm, and the surface roughness Ra of the surface of conductive connection member=1.0 μm to 3.0 μm. From these results, critical range of the surface roughness Ra of the bottom surface 4s of bore region 4a, and the surface roughness Ra of the surface of conductive connection member became clear.

As the same manner, as shown in the table 1 and the table 3, when the solder junction layer was made of aluminum (Al), the critical range of the surface roughness Ra of the bottom surface 4s of bore region 4a, and the surface roughness Ra of the surface of conductive connection member became clear by the following examples and comparative examples:

the examples 31 to 34 and the comparative examples 13-50 where the conductive connection member materials were niobium (Nb);

the examples 35 to 38 and the comparative examples 51-58 where the conductive connection member materials were platinum (Pt);

the examples 39 to 42 and the comparative examples 59-66 where the conductive connection member materials were Ti—Ni alloy.

As shown on the table 3, when the solder junction layer was made of aluminum (Al), it was found that comparative examples 67, 68, where the conductive connection member materials were molybdenum (Mo) or stainless steel (SUS304), and both the surface roughness Ra of the bottom surface 4s of bore region 4a and the surface roughness Ra of the surface of conductive connection member were in the range of the claimed invention were inferior in the joint strength. From these results, Ti, Nb, Pt, Ti—Ni alloy were preferable as conductive connection member materials.

### (Thermal Uniformity Test)

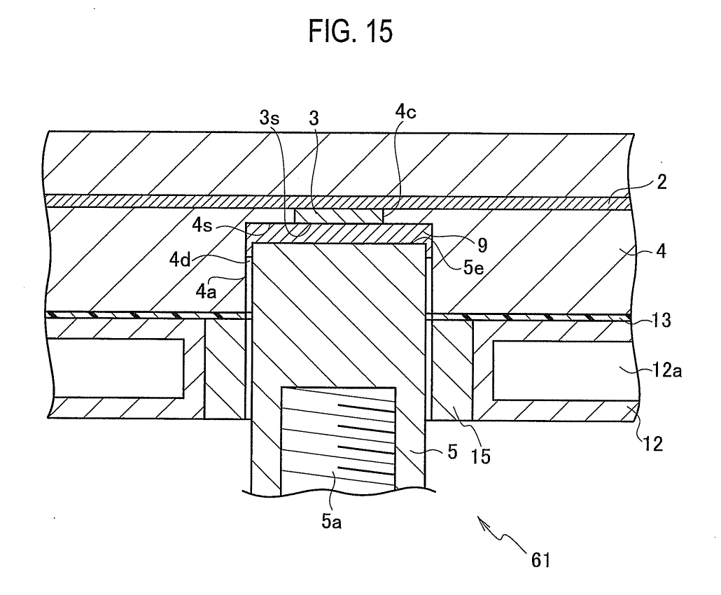

Similar to the manufacturing example of the body having a junction, the body having a junction composed of the connection member material and the solder junction layer was obtained as shown in the table 4. Then, an aluminum cooling plate was adhered through a thermal conductive resin sheet to the body having a junction. The electrostatic chuck shown in FIG. 15 was obtained.

After that, electric power was supplied to the inner electrode 2, and the ceramics member 4 was heated. Then, the thermal uniformity when an average temperature was set to 80° C. was evaluated by using thermo photography.

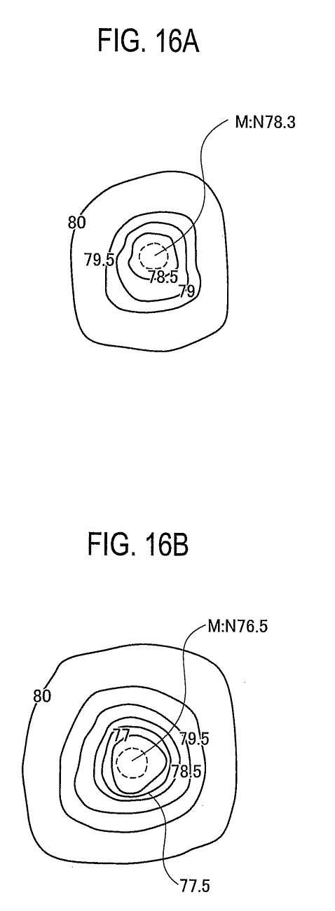

The result is shown in FIGS. 16A, 16B. FIGS. 16A, 16B show contour lines traced from the temperature distributions when the surface on the substrate placement side around the terminal 3 was measured by using thermo photography.

As a result, when the difference of the average temperature between the periphery of the terminal 3 and the surface of the ceramics member 4 was compared, it was −2.2° C. in the example, and it was −3.5° C. in the comparison example. Thus, the improvement of the thermal uniformity was recognized.

TABLE 4

| | SURFACE | SURFACE | | | |
|---|---|---|---|---|---|
| | ROUGHNESS OF | ROUGHNESS OF | MATERIAL OF | SOLDER | |
| | BOTTOM SURFACE | CONNECTION | CONNECTION | JUNCTION | |
| No. | OF BORE Ra(um) | MEMBER Ra(um) | MEMBER | LAYER | ΔTat 80° C. |
| EXAMPLE 43 | 1.0 | 2.1 | Ti | In | −2.2 |
| COMPARATIVE EXAMPLE 69 | 1.0 | 2.2 | Mo | In | −3.5 |

What is claimed is:

1. A body having a junction, comprising:
a ceramics member in which a plate-shaped inner electrode is embedded, having a bore region extending from a surface of the ceramics member to the inner electrode, a surface of a bottom surface of the bore region being made rough, and a terminal hole extending to the inner electrode being provided in a part of the bottom surface, and a main component of the ceramics member being alumina;
a conductive terminal embedded in the terminal hole, a bottom surface thereof is in contact with the inner electrode, and a top surface thereof is exposed at a horizontal level of the bottom surface of the bore region;
a solder junction layer in contact with the bottom surface of the bore region including the top surface; and
a conductive connection member having a lower end surface in contact with the solder junction layer with a lower portion inserted into the bore region, and having a thermal expansion coefficient in a range between about 6.5 and about 9.5 ppm/K.

2. The body having a junction according to claim 1, wherein the connection member includes a metal having a thermal conductivity of 50 W/mK or less.

3. The body having a junction according to claim 1, wherein the connection member includes a metal selected from a group consisting of Ti, Nb, Pt and alloys thereof;
the bottom surface of the bore region is surface roughness processed so that a surface roughness thereof is in a range of Ra=about 0.7 to about 2.0 μm;
the lower end surface of the connection member is made rough so that a surface roughness is in a range of Ra=about 1 to about 3 μm.

4. The body having a junction according to claim 1, further including a plating layer including Ni provided between the bottom surface of the bore region and the solder junction layer.

5. The body having a junction according to claim 1, wherein on a section of the ceramics member parallel to the surface of the ceramics member, a semi-circular solder retaining space is installed in a part of a side wall of the bore region, and the solder junction layer fills a part of the solder retaining space so that the connection member is embedded in the part of the solder retaining space, a part on an outer circumferential surface of the connection member further having a key portion engaged with the solder stay space.

6. The body having a junction according claim 1, wherein the connection member includes a notch on a part of the outer circumferential surface of the connection member that is at least partly filled by the solder junction layer.

7. A method of manufacturing a body having a junction, comprising:
forming a plate-shaped inner electrode on a top surface of a first ceramics layer having a main component of alumina;
placing a terminal made of sinter on the inner electrode so that a bottom surface thereof is in contact with a part of a top surface of the inner electrode;
covering the terminal and the inner electrode by placing a baking material having a main component of alumina and baking the baking material and consequently providing a second ceramics layer so as to obtain a ceramics member in which the inner electrode and the terminal are embedded between the first ceramics layer and the second ceramics layer;
forming a bore region extending from a surface of the ceramics member to the inner electrode and exposing a top surface of the terminal to a part of a bottom surface of the bore region;
roughing the bottom surface of the bore so that a surface roughness of the bottom surface of the bore is in a range of Ra=about 0.7 to about 2.0 μm;
forming a plating layer including Ni between the bottom surface and a joining material layer;
forming a solder junction layer on the bottom surface of the bore region including the top surface of the terminal; and
roughing a contact surface with the solder junction layer so that a surface roughness Ra is in a range of about 1 to about 3 μm, and inserting a lower portion of the connection member into the bore region so that a lower end surface of a conductive connection member having a thermal expansion coefficient in a range of about 6.5 and about 9.5 ppm/K is in contact with the solder junction layer.
